(19) United States
(12) Patent Application Publication
(10) Pub. No.: US 2026/0337765 A1
(43) Pub. Date: Oct. 29, 2026

(54) VACUUM PUMP PARTICLE TRAP, VACUUM PUMP, SEMICONDUCTOR MANUFACTURING APPARATUS

(71) Applicants: Kabushiki Kaisha Toshiba, Kawasaki-shi (JP); Toshiba Electronic Devices & Storage Corporation, Kawasaki-shi (JP)

(72) Inventor: Kazuto WAGAWA, Kitakami Iwate (JP)

(21) Appl. No.: 19/375,022

(22) Filed: Oct. 30, 2025

(30) Foreign Application Priority Data
Mar. 24, 2025 (JP) 2025-048747

(51) Int. Cl. C23C 16/44; H10P 72/00

(52) U.S. Cl. CPC C23C 16/4412; C23C 16/4408; H10P 72/0402

(57) ABSTRACT

A vacuum pump particle trap according to an embodiment includes: a first pipe having a first end, a second end, a first opening, a second opening, and a first center line extending in a first direction; a second pipe having a second center line extending in a second direction orthogonal to the first direction, the second pipe connected to side of the first pipe; a third pipe having a fifth end, a sixth end, and a third center line partially extending in the second direction, the third pipe connected to a portion opposite to the second pipe of the first pipe; a first plate closing the first opening; and a second plate closing the second opening, the fifth end provided inside the first pipe, and the third pipe bending inside the first pipe in a direction that the fifth end approaches the first plate.

### CROSS-REFERENCE TO RELATED APPLICATION

This application is based upon and claims the benefit of priority from Japanese Patent Application No. 2025-048747, filed on Mar. 24, 2025, the entire contents of which are incorporated herein by reference.

### FIELD

Embodiments described herein relate generally to a vacuum pump particle trap, a vacuum pump, and a semiconductor manufacturing apparatus.

### BACKGROUND

A semiconductor device is manufactured through various processes such as film formation and film etching. For example, in a chemical vapor deposition method (CVD method), a source gas is supplied into a chamber decompressed by a vacuum pump to deposit a film on a semiconductor substrate. An exhaust gas such as the source gas not consumed for the film formation is discharged from the inside of the chamber to an exhaust pipe using the vacuum pump.

For example, a reaction product is deposited on an inner wall of the exhaust pipe due to the exhaust gas discharged from the inside of the chamber. The reaction product deposited on the inner wall of the exhaust pipe may be peeled off to become particles, and the particles may enter the vacuum pump. When the particles enter the vacuum pump, the performance of the vacuum pump may deteriorate, or the vacuum pump may fail.

### BRIEF DESCRIPTION OF THE DRAWINGS

FIG. 1 is a schematic view of a semiconductor manufacturing apparatus including a vacuum pump particle trap according to a first embodiment;

FIG. 2 is a perspective view of the vacuum pump particle trap according to the first embodiment;

FIG. 3 is a cross-sectional view of the vacuum pump particle trap according to the first embodiment;

FIG. 4 is a cross-sectional view of the vacuum pump particle trap according to the first embodiment;

FIG. 5 is an explanatory view of a function and an effect of the vacuum pump particle trap according to the first embodiment;

FIG. 6 is a cross-sectional view of a vacuum pump particle trap according to a first modification of the first embodiment;

FIG. 7 is a cross-sectional view of a vacuum pump particle trap according to a second modification of the first embodiment;

FIG. 8 is a cross-sectional view of a vacuum pump particle trap according to a third modification of the first embodiment;

FIG. 9 is a cross-sectional view of a vacuum pump particle trap according to a fourth modification of the first embodiment; and

FIG. 10 is a side view of a vacuum pump particle trap according to a second embodiment.

### DETAILED DESCRIPTION

A vacuum pump particle trap according to an aspect of the present disclosure includes: a first pipe having a first end, a second end, a first opening on a side of the first end, a second opening on a side of the second end, a first inner diameter, and a first center line extending in a first direction; a second pipe having a third end, a fourth end, a third opening on a side of the third end, a fourth opening on a side of the fourth end, a second inner diameter smaller than the first inner diameter, and a second center line extending in a second direction orthogonal to the first direction, the second pipe being connected to a side face of the first pipe; a third pipe having a fifth end, a sixth end, a fifth opening on a side of the fifth end, a sixth opening on a side of the sixth end, a third inner diameter smaller than the first inner diameter, and a third center line at least a part of which extends in the second direction, the third pipe being connected to a portion of the side face on a side opposite to the second pipe across the first pipe; a first plate closing the first opening; and a second plate closing the second opening, the fifth end being provided inside the first pipe, and the third pipe bending inside the first pipe in a direction in which the fifth end approaches the first plate.

In this specification, the same or similar members will be denoted by the same reference numerals, and redundant descriptions thereof will be omitted in some cases.

### First Embodiment

A vacuum pump particle trap according to a first embodiment includes: a first pipe having a first end, a second end, a first opening on a side of the first end, a second opening on a side of the second end, a first inner diameter, and a first center line extending in a first direction; a second pipe having a third end, a fourth end, a third opening on a side of the third end, a fourth opening on a side of the fourth end, a second inner diameter smaller than the first inner diameter, and a second center line extending in a second direction orthogonal to the first direction, the second pipe being connected to a side face of the first pipe; a third pipe having a fifth end, a sixth end, a fifth opening on a side of the fifth end, a sixth opening on a side of the sixth end, a third inner diameter smaller than the first inner diameter, and a third center line at least a part of which extends in the second direction, the third pipe being connected to a portion of the side face on a side opposite to the second pipe across the first pipe; a first plate closing the first opening; and a second plate closing the second opening, the fifth end being provided inside the first pipe, and the third pipe bending inside the first pipe in a direction in which the fifth end approaches the first plate.

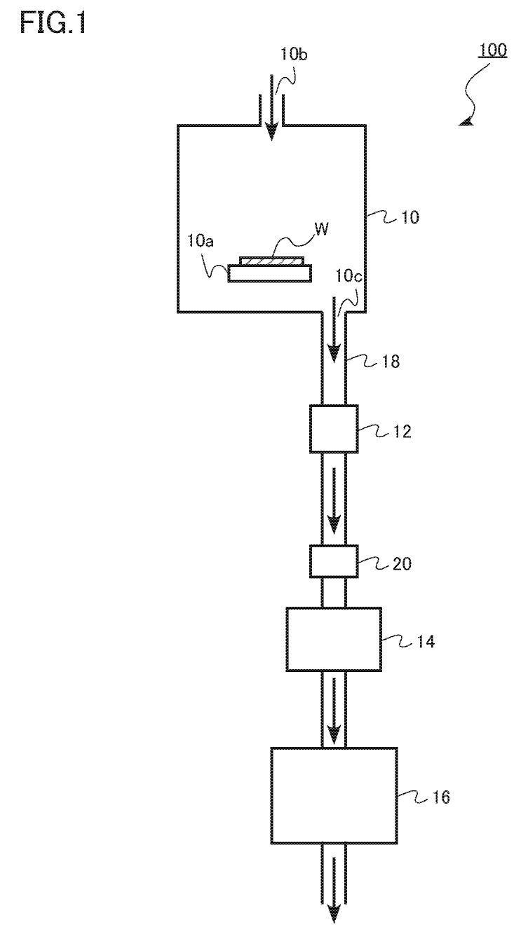

FIG. 1 is a schematic view of a semiconductor manufacturing apparatus including the vacuum pump particle trap according to the first embodiment. The semiconductor manufacturing apparatus is a CVD apparatus 100.

The CVD apparatus 100 includes a chamber 10, a pressure control valve 12, a vacuum pump 14, a detoxifying device 16, a gas pipe 18, and a vacuum pump particle trap 20.

The chamber 10 includes a susceptor 10a, a gas supply port 10b, and a gas exhaust port 10c. In the chamber 10, a film is deposited on a semiconductor substrate W.

For the film deposition on the semiconductor substrate W, the semiconductor substrate W is placed on the susceptor 10a. The semiconductor substrate W is heated by a heater (not illustrated). A source gas of the film is caused to flow from the gas supply port 10b, and the film is deposited on the semiconductor substrate W. An exhaust gas such as the source gas not consumed for film formation is discharged from the gas exhaust port 10c to the outside of the chamber 10.

The pressure control valve 12 is provided downstream of the chamber 10. The pressure control valve 12 has a function of adjusting the pressure in the chamber 10.

The vacuum pump 14 is provided downstream of the pressure control valve 12. The vacuum pump 14 has a function of reducing the pressure in the chamber 10. The vacuum pump 14 is, for example, a dry pump.

The detoxifying device 16 is provided downstream of the vacuum pump 14. The detoxifying device 16 has a function of detoxifying the exhaust gas discharged from the chamber 10. The detoxified exhaust gas passing through the detoxifying device 16 is discharged to the outside of the CVD apparatus 100.

The gas pipe 18 connects the chamber 10, the pressure control valve 12, the vacuum pump 14, and the detoxifying device 16 to each other. The gas pipe 18 serves as a flow path of the exhaust gas discharged from the chamber 10.

The vacuum pump particle trap 20 is provided, for example, in the gas pipe 18 between the pressure control valve 12 and the vacuum pump 14. The vacuum pump particle trap 20 has a function of suppressing particles from entering the vacuum pump 14.

Note that the vacuum pump particle trap 20 may be integrated with the vacuum pump 14 as a part of the vacuum pump 14, for example.

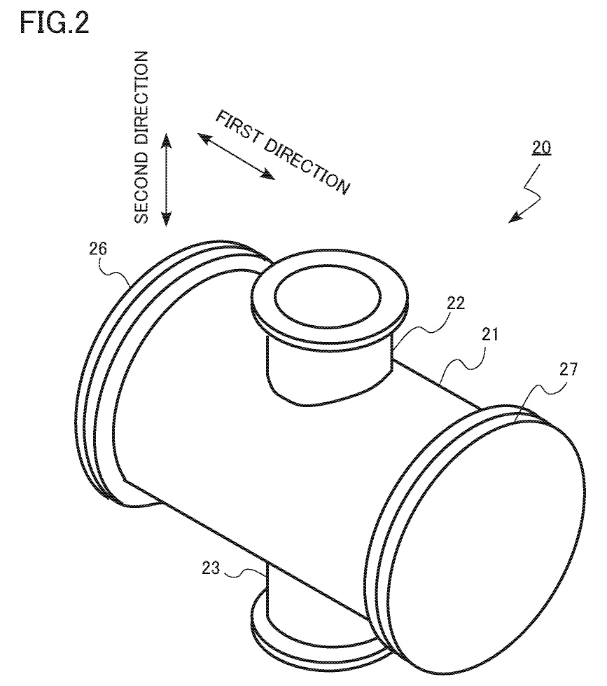

FIG. 2 is a perspective view of the vacuum pump particle trap according to the first embodiment.

The vacuum pump particle trap 20 according to the first embodiment includes a main body pipe 21 (first pipe), an intake pipe 22 (second pipe), an exhaust pipe 23 (third pipe), a first plate 26, a second plate 27, and an O-ring 29.

The intake pipe 22 is connected to, for example, the gas pipe 18 on the chamber 10 side. The exhaust pipe 23 is connected to, for example, the gas pipe 18 on the vacuum pump 14 side.

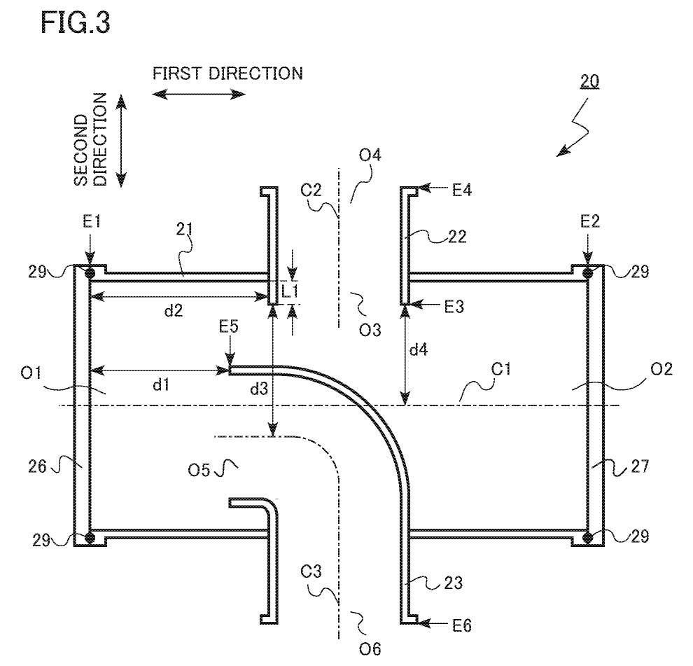

FIG. 3 is a cross-sectional view of the vacuum pump particle trap according to the first embodiment. FIG. 3 is an example of a first cross section.

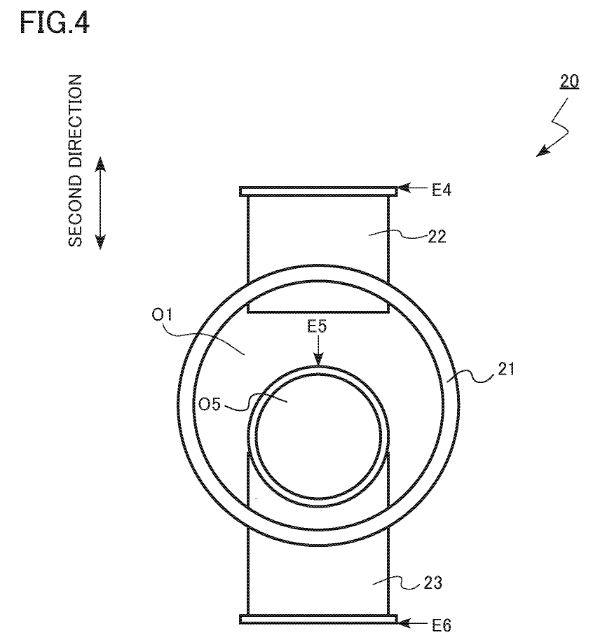

FIG. 4 is a side view of the vacuum pump particle trap according to the first embodiment. The side view in a state where the first plate 26 is removed is viewed from the first plate 26 side.

The main body pipe 21 has a first end E1, a second end E2, a first opening O1, a second opening O2, a first inner diameter φ1, and a first center line C1. The main body pipe 21 has, for example, a cylindrical shape.

The first opening O1 of the main body pipe 21 is provided on the first end E1 side. The second opening O2 is provided on the second end E2 side. The first center line C1 extends in a first direction.

The first inner diameter φ1 of the main body pipe 21 is, for example, equal to or more than 100 mm and equal to or less than 400 mm. The main body pipe 21 is made of, for example, stainless steel (SUS).

The intake pipe 22 is connected to a side face of the main body pipe 21.

The intake pipe 22 has a third end E3, a fourth end E4, a third opening O3, a fourth opening O4, a second inner diameter φ2, and a second center line C2. The intake pipe 22 has, for example, a cylindrical shape.

The third opening O3 of the intake pipe 22 is provided on the third end E3 side. The fourth end E4 is provided on the fourth end E4 side. The second center line C2 of the intake pipe 22 extends in a second direction orthogonal to the first direction.

The second inner diameter φ2 of the intake pipe 22 is smaller than the first inner diameter φ1. The second inner diameter φ2 is, for example, equal to or more than 50 mm and equal to or less than 200 mm. The intake pipe 22 is made of, for example, stainless steel (SUS).

The exhaust pipe 23 is connected to a side face of the main body pipe 21. The exhaust pipe 23 is connected to a portion of the side face of the main body pipe 21 on a side opposite to the intake pipe 22 across the main body pipe 21.

The exhaust pipe 23 has a fifth end E5, a sixth end E6, a fifth opening O5, a sixth opening O6, a third inner diameter φ3, and a third center line C3. The exhaust pipe 23 has, for example, a cylindrical shape.

The fifth opening O5 of the exhaust pipe 23 is provided on the fifth end E5 side. The sixth opening O6 is provided on the sixth end E6 side.

At least a part of the third center line C3 of the exhaust pipe 23 extends in the second direction.

The third inner diameter φ3 of the exhaust pipe 23 is smaller than the first inner diameter φ1. The third inner diameter φ3 is, for example, equal to or more than 50 mm and equal to or less than 200 mm. The exhaust pipe 23 is made of, for example, stainless steel (SUS).

The first plate 26 closes the first opening O1 of the main body pipe 21. The second plate 27 closes the second opening O2 of the main body pipe 21.

The fifth end E5 of the exhaust pipe 23 is provided inside the main body pipe 21. The sixth end E6 of the exhaust pipe 23 is provided outside the main body pipe 21, for example.

The exhaust pipe 23 is bent inside the main body pipe 21. The exhaust pipe 23 is, for example, an L-shaped pipe.

The exhaust pipe 23 bends in a direction in which the fifth end E5 approaches the first plate 26 inside the main body pipe 21. The exhaust pipe 23 bends in a direction in which the fifth opening O5 faces the first plate 26 inside the main body pipe 21.

The third center line C3 in the vicinity of the fifth opening O5 of the exhaust pipe 23 extends, for example, in the first direction. The third center line C3 in the vicinity of the sixth opening O6 of the exhaust pipe 23 extends, for example, in the second direction. The third center line C3 of the exhaust pipe 23 outside the main body pipe 21 extends, for example, in the second direction.

A first distance (d1 in FIG. 3) in the first direction between the fifth end E5 of the exhaust pipe 23 and the first plate 26 is, for example, smaller than a second distance (d2 in FIG. 3) in the first direction between the third end E3 of the intake pipe 22 and the first plate 26. The first distance d1 is, for example, equal to or more than 1 time and equal to or less than 4 times the second inner diameter φ2 of the intake pipe 22.

A line obtained by extending the second center line C2 of the intake pipe 22 overlaps, for example, the third center line C3 of the exhaust pipe 23 in the vicinity of the sixth opening O6 of the exhaust pipe 23. A line obtained by extending the second center line C2 of the intake pipe 22 overlaps, for example, the third center line C3 of the exhaust pipe 23 outside the main body pipe 21. The intake pipe 22 and the exhaust pipe 23 outside the main body pipe 21 are provided coaxially.

As illustrated in FIG. 3, in the first cross section, which includes the first center line C1 of the main body pipe 21 and is parallel to the first direction and the second direction, a side face of the exhaust pipe 23 inside the main body pipe 21 on the intake pipe 22 side is a curved face. In the first cross section, the side face of the exhaust pipe 23 inside the main body pipe 21 on the intake pipe 22 side is an inclined face whose distance from the intake pipe 22 increases toward the second plate 27.

A third distance (d3 in FIG. 3) in the second direction between the third center line C3 in the vicinity of the fifth opening O5 of the exhaust pipe 23 and the third end E3 of the intake pipe 22 is larger than, for example, a fourth distance (d4 in FIG. 3) in the second direction between the first center line C1 of the main body pipe 21 and the third end E3.

The third end E3 of the intake pipe 22 is provided inside the main body pipe 21, for example. A first length (L1 in FIG. 3) in the second direction of the intake pipe 22 inside the main body pipe 21 is, for example, equal to or more than 1/20 and equal to or less than 1/5 of the second inner diameter φ2 of the intake pipe 22.

The first plate 26 is, for example, separable from the main body pipe 21. The second plate 27 is, for example, separable from the main body pipe 21.

The first plate 26 and the second plate 27 are, for example, blank flanges. The first plate 26 and the second plate 27 are fixed to the main body pipe 21 using, for example, clamps (not illustrated).

For example, the O-ring 29 is provided between the first plate 26 and the main body pipe 21. For example, the O-ring 29 is provided between the second plate 27 and the main body pipe 21. Since the O-rings 29 are provided, leakage of the exhaust gas is suppressed.

Next, a function and an effect of the vacuum pump particle trap 20 according to the first embodiment will be described.

When a film is deposited on the semiconductor substrate W using the CVD apparatus 100 as illustrated in FIG. 1, the exhaust gas such as the source gas not consumed for formation of the film is discharged from the inside of the chamber 10 to the gas pipe 18 using the vacuum pump 14.

For example, a reaction product is deposited on an inner wall of the gas pipe 18 due to the exhaust gas discharged from the inside of the chamber 10. Then, for example, in a case where the vacuum pump particle trap 20 is not provided in the CVD apparatus 100, the reaction product deposited on the inner wall of the gas pipe 18 may be peeled off to become particles, and the particles may enter the vacuum pump 14. When the particles enter the vacuum pump, the performance of the vacuum pump 14 may deteriorate or the vacuum pump 14 may fail. Therefore, it is desirable to suppress the entry of particles into the vacuum pump 14.

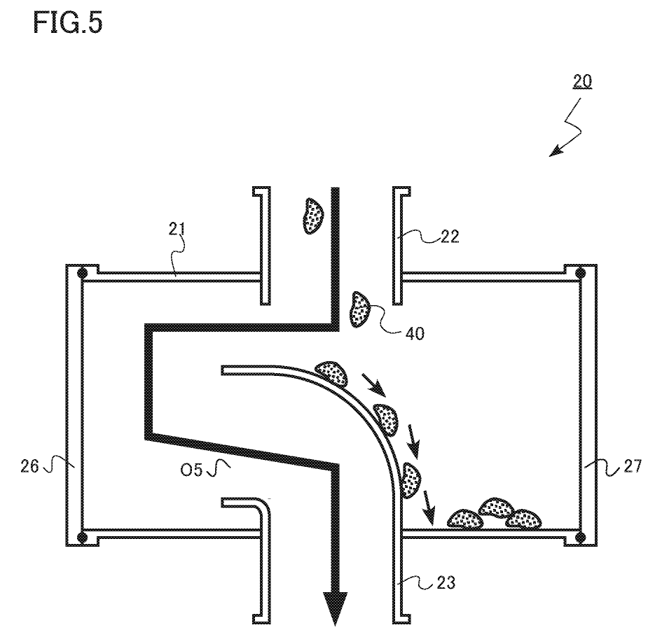

FIG. 5 is an explanatory view of the function and effect of the vacuum pump particle trap according to the first embodiment. FIG. 5 is a cross-sectional view corresponding to FIG. 3.

In FIG. 5, a flow of the exhaust gas is indicated by an arrow. FIG. 5 illustrates particles 40 contained in the exhaust gas.

As illustrated in FIG. 5, the exhaust gas flows from the intake pipe 22 into the main body pipe 21. The exhaust gas having flowed in collides with the side face of the exhaust pipe 23 and flows toward the first plate 26 side. The exhaust gas flowing toward the first plate 26 enters the exhaust pipe 23 from the fifth opening O5 of the exhaust pipe 23 and is discharged to the outside from the main body pipe 21.

As illustrated in FIG. 5, the particles 40 contained in the exhaust gas collide with the side face of the exhaust pipe 23 and fall toward the second plate 27 side along the inclination of the side face. The particles 40 that have fallen to the second plate 27 side accumulate at a bottom of the main body pipe 21. Therefore, the particles 40 are prevented from entering the exhaust pipe 23 and being discharged from the main body pipe 21 to the outside.

The particles 40 contained in the exhaust gas are captured by the vacuum pump particle trap 20, and the entry of the particles 40 into the vacuum pump 14 is suppressed. Therefore, since the vacuum pump particle trap 20 is used, it is possible to suppress the deterioration in the performance of the vacuum pump 14 or the failure of the vacuum pump 14.

From the viewpoint of suppressing the particles 40 contained in the exhaust gas from flowing into the exhaust pipe 23, the first distance (d1 in FIG. 3) in the first direction between the fifth end E5 of the exhaust pipe 23 and the first plate 26 is preferably smaller than the second distance (d2 in FIG. 3) in the first direction between the third end E3 of the intake pipe 22 and the first plate 26.

From the viewpoint of expanding the flow path of the exhaust gas and increasing the conductance of the exhaust gas in the vacuum pump particle trap 20, the first distance (d1 in FIG. 3) in the first direction between the fifth end E5 of the exhaust pipe 23 and the first plate 26 is preferably large. The first distance d1 is preferably equal to or more than 1 time, more preferably equal to or more than 1.5 times the second inner diameter φ2 of the intake pipe 22.

From the viewpoint of expanding the flow path of the exhaust gas and increasing the conductance of the exhaust gas in the vacuum pump particle trap 20, the third distance (d3 in FIG. 3) in the second direction between the third center line C3 in the vicinity of the fifth opening O5 of the exhaust pipe 23 and the third end E3 of the intake pipe 22 is preferably larger than the fourth distance (d4 in FIG. 3) in the second direction between the first center line C1 and the third end E3 of the main body pipe 21.

The third end E3 of the intake pipe 22 is preferably provided inside the main body pipe 21 from the viewpoint of suppressing the exhaust gas from flowing from the third end E3 of the intake pipe 22 to an upper face of the inner wall of the main body pipe 21 and suppressing the reaction product from adhering to the upper face of the inner wall of the main body pipe 21. From the above viewpoint, the first length (L1 in FIG. 3) in the second direction of the intake pipe 22 inside the main body pipe 21 is preferably equal to or more than 1/20, more preferably equal to or more than 1/10 of the second inner diameter φ2 of the intake pipe 22.

From the viewpoint of facilitating maintenance of the vacuum pump particle trap 20, the first plate 26 and the second plate 27 are preferably separable from the main body pipe 21. For example, either the first plate 26 or the second plate 27 may be configured to be separable from the main body pipe 21. In addition, if ease of maintenance is sacrificed, both the first plate 26 and the second plate 27 may be configured to be inseparable from the main body pipe 21.

Although the case where the main body pipe 21, the intake pipe 22, and the exhaust pipe 23 have cylindrical shapes has been described as an example, the main body pipe 21, the intake pipe 22, and the exhaust pipe 23 are not necessarily limited to the cylindrical shapes.

With the vacuum pump particle trap 20 according to the first embodiment, it is possible to suppress the particles 40 contained in the exhaust gas from entering the vacuum pump 14.

### First Modification

In a vacuum pump particle trap according to a first modification of the first embodiment, a distance in a first direction between a first plate and a fifth end on a side closer to a second pipe is smaller than a distance in the first direction between the first plate and the fifth end on a side farther from the second pipe in a first cross section, which includes a first center line and is parallel to the first direction and the second direction.

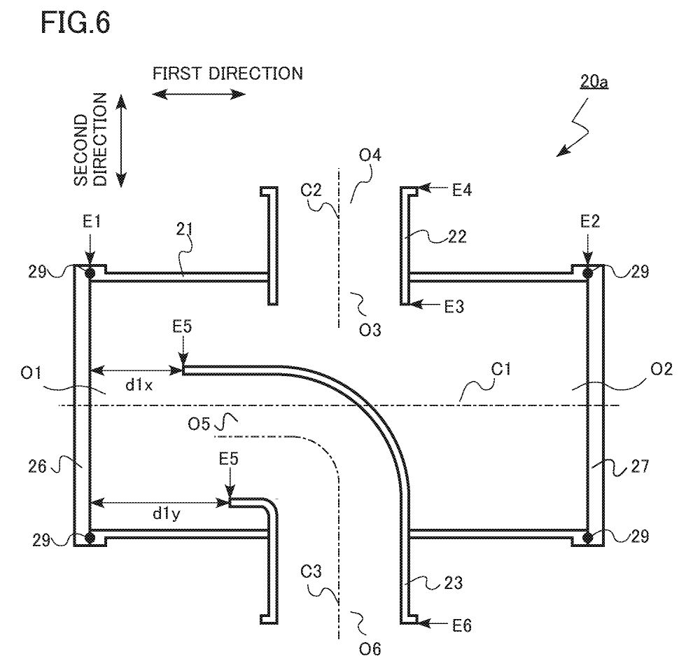

FIG. 6 is a cross-sectional view of the vacuum pump particle trap according to the first modification of the first embodiment. FIG. 6 is a view corresponding to FIG. 3 of the first embodiment. FIG. 6 is an example of the first cross section.

As illustrated in FIG. 6, in the first cross section of a vacuum pump particle trap 20a according to the first modification of the first embodiment, a distance (d1x in FIG. 6) in a first direction between the first plate 26 and the fifth end E5 of the exhaust pipe 23 on a side closer to the intake pipe 22 is smaller than a distance (d1y in FIG. 6) in the first direction between the first plate 26 and the fifth end E5 on a side farther from the intake pipe 22.

With the vacuum pump particle trap 20a according to the first modification, for example, the particles 40 contained in an exhaust gas are further suppressed from entering the exhaust pipe 23.

With the vacuum pump particle trap 20a according to the first modification of the first embodiment, it is possible to suppress the particles 40 contained in the exhaust gas from entering the vacuum pump 14.

### Second Modification

In a vacuum pump particle trap according to a second modification of the first embodiment, a distance in a first direction between a first plate and a fifth end on a side closer to a second pipe is larger than a distance in the first direction between the first plate and the fifth end on a side farther from the second pipe in a first cross section, which includes a first center line and is parallel to the first direction and the second direction.

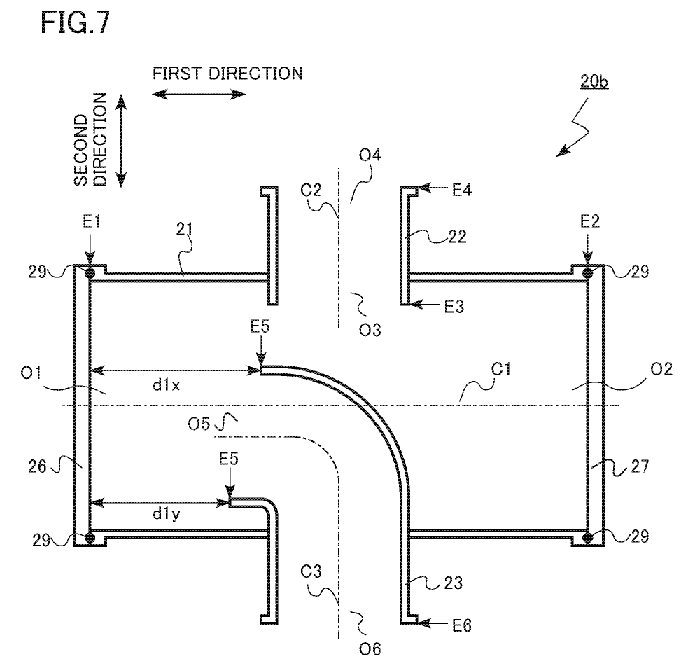

FIG. 7 is a cross-sectional view of the vacuum pump particle trap according to the second modification of the first embodiment. FIG. 7 is a view corresponding to FIG. 3 of the first embodiment. FIG. 7 is an example of the first cross section.

As illustrated in FIG. 7, in the first cross section of a vacuum pump particle trap 20b according to the second modification of the first embodiment, a distance (d1x in FIG. 7) in a first direction between the first plate 26 and the fifth end E5 of the exhaust pipe 23 on a side closer to the intake pipe 22 is larger than a distance (d1y in FIG. 7) in the first direction between the first plate 26 and the fifth end E5 on a side farther from the intake pipe 22.

With the vacuum pump particle trap 20b according to the second modification, for example, a flow path of an exhaust gas can be expanded, and the conductance of the exhaust gas in the vacuum pump particle trap 20b can be increased.

With the vacuum pump particle trap 20b according to the second modification of the first embodiment, it is possible to suppress the particles 40 contained in the exhaust gas from entering the vacuum pump 14.

### Third Modification

In a vacuum pump particle trap according to a third modification of the first embodiment, a third end of a second pipe is not provided inside a first pipe.

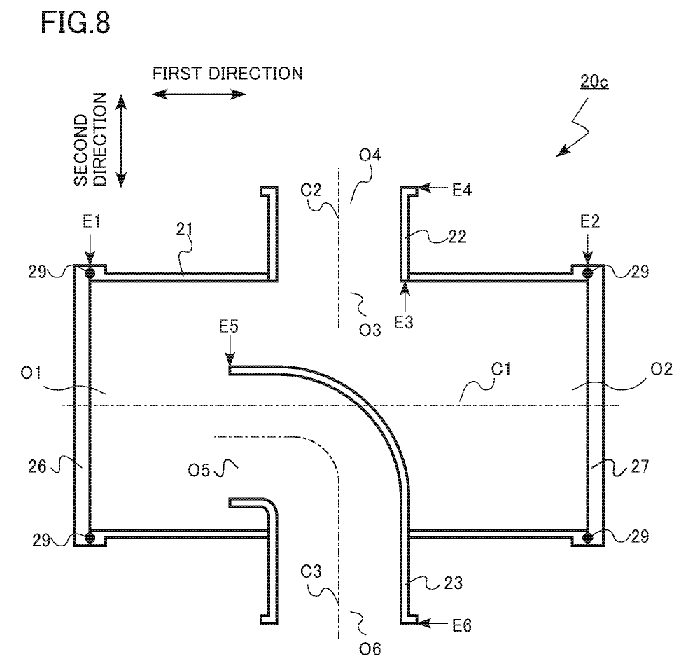

FIG. 8 is a cross-sectional view of the vacuum pump particle trap according to the third modification of the first embodiment. FIG. 8 is a view corresponding to FIG. 3 of the first embodiment.

As illustrated in FIG. 8, the third end E3 of the intake pipe 22 of a vacuum pump particle trap 20c according to the third modification of the first embodiment is not provided inside the main body pipe 21.

With the vacuum pump particle trap 20c according to the third modification, for example, a flow path of an exhaust gas can be expanded, and the conductance of the exhaust gas in the vacuum pump particle trap 20c can be increased.

With the vacuum pump particle trap 20c according to the third modification of the first embodiment, it is possible to suppress the particles 40 contained in the exhaust gas from entering the vacuum pump 14.

### Fourth Modification

In a vacuum pump particle trap according to a fourth modification of the first embodiment, a line obtained by extending a second center line does not overlap a third center line of a third pipe in the vicinity of a sixth opening. In addition, the third center line of the third pipe in the vicinity of the sixth opening is closer to a first plate than the second center line.

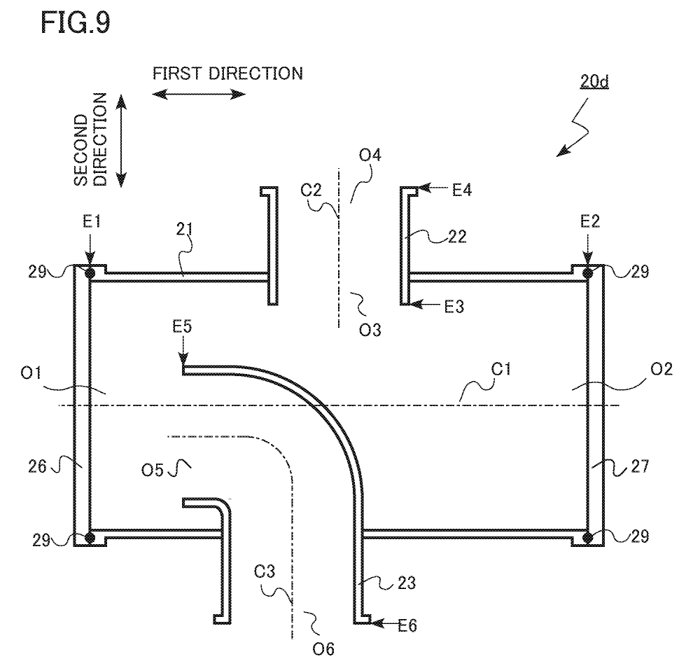

FIG. 9 is a cross-sectional view of the vacuum pump particle trap according to the fourth modification of the first embodiment. FIG. 9 is a view corresponding to FIG. 3 of the first embodiment.

As illustrated in FIG. 9, in a vacuum pump particle trap 20d according to the fourth modification of the first embodiment, a line obtained by extending the second center line C2 of the intake pipe 22 does not overlap the third center line C3 of the exhaust pipe 23 in the vicinity of the sixth opening O6 of the exhaust pipe 23. The third center line C3 of the exhaust pipe 23 in the vicinity of the sixth opening O6 of the exhaust pipe 23 is closer to the first plate 26 than the second center line C2 of the intake pipe 22.

With the vacuum pump particle trap 20d according to the fourth modification, for example, the particles 40 contained in an exhaust gas are further suppressed from entering the exhaust pipe 23.

With the vacuum pump particle trap 20d according to the fourth modification of the first embodiment, it is possible to suppress the particles 40 contained in the exhaust gas from entering the vacuum pump 14.

As described above, according to the first embodiment and the modifications, it is possible to achieve the vacuum pump particle trap that suppresses the entry of particles into the vacuum pump.

### Second Embodiment

A vacuum pump particle trap according to a second embodiment is different from the vacuum pump particle trap according to the first embodiment in terms of further including a filter that covers a fifth opening. Hereinafter, some of the content overlapping with that in the first embodiment will not be described in some cases.

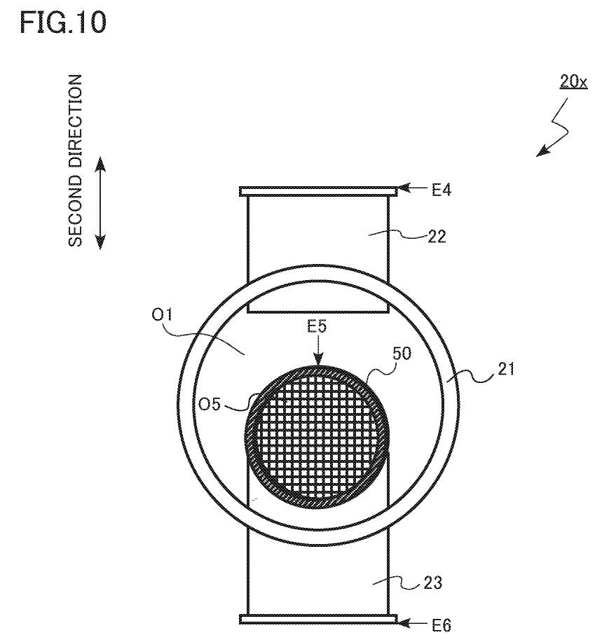

FIG. 10 is a side view of the vacuum pump particle trap according to the second embodiment. FIG. 10 is a view corresponding to FIG. 4 of the first embodiment.

A vacuum pump particle trap 20x according to the second embodiment includes the main body pipe 21 (first pipe), the intake pipe 22 (second pipe), the exhaust pipe 23 (third pipe), the first plate 26, the second plate 27, the O-ring 29, and a filter 50.

The filter 50 covers the fifth opening O5 of the exhaust pipe 23. The filter 50 is, for example, a meshed center ring.

The filter 50 prevents the particles 40 contained in an exhaust gas from entering the exhaust pipe 23.

As described above, according to the second embodiment, it is possible to achieve the vacuum pump particle trap that suppresses the entry of particles into the vacuum pump.

Although the CVD apparatus has been described as an example of the semiconductor manufacturing apparatus in the first and second embodiments, the semiconductor manufacturing apparatus of the present disclosure is not limited to the CVD apparatus, and can be applied to other semiconductor manufacturing apparatuses using vacuum pumps.

Although the dry pump has been described as an example of the vacuum pump in the first and second embodiments, the vacuum pump of the present disclosure is not limited to the dry pump, and can be applied to other vacuum pumps.

While certain embodiments have been described, these embodiments have been presented by way of example only, and are not intended to limit the scope of the inventions. Indeed, the vacuum pump particle trap, the vacuum pump, and the semiconductor manufacturing apparatus described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A vacuum pump particle trap comprising:
a first pipe having a first end, a second end, a first opening on a side of the first end, a second opening on a side of the second end, a first inner diameter, and a first center line extending in a first direction;
a second pipe having a third end, a fourth end, a third opening on a side of the third end, a fourth opening on a side of the fourth end, a second inner diameter smaller than the first inner diameter, and a second center line extending in a second direction orthogonal to the first direction, the second pipe being connected to a side face of the first pipe;
a third pipe having a fifth end, a sixth end, a fifth opening on a side of the fifth end, a sixth opening on a side of the sixth end, a third inner diameter smaller than the first inner diameter, and a third center line at least a part of which extends in the second direction, the third pipe being connected to a portion of the side face on a side opposite to the second pipe across the first pipe;
a first plate closing the first opening; and
a second plate closing the second opening,
wherein the fifth end is provided inside the first pipe, and the third pipe bends inside the first pipe in a direction in which the fifth end approaches the first plate.

2. The vacuum pump particle trap according to claim 1, wherein the third center line in a vicinity of the fifth opening extends in the first direction.

3. The vacuum pump particle trap according to claim 1, wherein the sixth end is provided outside the first pipe, and the third center line in a vicinity of the sixth opening extends in the second direction.

4. The vacuum pump particle trap according to claim 3, wherein a line obtained by extending the second center line overlaps the third center line of the third pipe in a vicinity of the sixth opening.

5. The vacuum pump particle trap according to claim 1, wherein a first distance in the first direction between the fifth end and the first plate is smaller than a second distance in the first direction between the third end and the first plate.

6. The vacuum pump particle trap according to claim 5, wherein the first distance is equal to or more than 1 time and equal to or less than 4 times the second inner diameter.

7. The vacuum pump particle trap according to claim 1, wherein a third distance in the second direction between the third center line in a vicinity of the fifth opening and the third end is larger than a fourth distance in the second direction between the first center line and the third end.

8. The vacuum pump particle trap according to claim 1, wherein a side face of the third pipe inside the first pipe on a side of the second pipe is a curved face in a first cross section, the first cross section includes the first center line and is parallel to the first direction and the second direction.

9. The vacuum pump particle trap according to claim 1, wherein the third end is provided inside the first pipe.

10. The vacuum pump particle trap according to claim 1, wherein a first length of the second pipe inside the first pipe in the second direction is equal to or more than 1/20 and equal to or less than 1/5 of the second inner diameter.

11. The vacuum pump particle trap according to claim 1, wherein the first inner diameter is equal to or more than 1.5 times and equal to or less than 5 times the second inner diameter and the third inner diameter.

12. The vacuum pump particle trap according to claim 1, wherein the first plate and the second plate are separable from the first pipe.

13. The vacuum pump particle trap according to claim 1, further comprising a filter covering the fifth opening.

14. A vacuum pump comprising the vacuum pump particle trap according to claim 1.

15. A semiconductor manufacturing apparatus comprising the vacuum pump particle trap according to claim 1.
